(19) United States
(12) Patent Application Publication
(10) Pub. No.: US 2005/0009210 A1
(43) Pub. Date: Jan. 13, 2005

(54) Magnetic random access memory and method of manufacturing the same

(76) Inventor: Keiji Hosotani, Tokyo (JP)

Correspondence Address: OBLON, SPIVAK, MCCLELLAND, MAIER & NEUSTADT, P.C., 1940 DUKE STREET, ALEXANDRIA, VA, 22314, US

(21) Appl. No.: 10/806,388

(22) Filed: Mar. 23, 2004

(30) Foreign Application Priority Data
Jul. 10, 2003 (JP) 2003-195187
Mar. 18, 2004 (JP) 2004-077814

(51) Int. Cl. H01L 21/00

(52) U.S. Cl. 438/3

(57) ABSTRACT

A magnetic random access memory includes a silicon substrate, a transistor which has a gate electrode formed on the silicon substrate via a gate insulating film and diffusion layers formed in the silicon substrate, a first insulating film formed on the silicon substrate and the transistor, a multilayered interconnection formed in the first insulating film, and a magneto-resistive element formed above the first insulating film, wherein at least some of dangling bonds in the silicon substrate are terminated by silicon-deuterium bonds.

### CROSS-REFERENCE TO RELATED APPLICATIONS

This application is based upon and claims the benefit of priority from prior Japanese Patent Applications No. 2003-195187, filed Jul. 10, 2003; and No. 2004-077814, filed Mar. 18, 2004, the entire contents of both of which are incorporated herein by reference.

### BACKGROUND OF THE INVENTION

1. Field of the Invention

The present invention relates to a magnetic random access memory and a method of manufacturing the same.

2. Description of the Related Art

In recent years, MRAMs (Magnetic Random Access Memories) in which each memory cell has an MTJ (Magnetic Tunnel Junction) element using a TMR (Tunneling Magneto-Resistive) effect have been proposed. The MRAMs have recently received a great deal of attention as ideal memories that combine the high processing speed, random access property, and nonvolatility of RAMs.

However, MRAMs which merge magnetic materials and semiconductors have new problems that are not posed in conventional semiconductor devices. One of the problems is related to the sintering process of a CMOS circuit used in an MRAM.

In a conventional CMOS circuit process, a process called “sintering” is executed at the final stage of the wafer process to remove damage introduced into the CMOS circuit during the process. In the sintering process, annealing is executed in a hydrogen atmosphere at about 400° C. or 450° C. With this sintering process, dangling bond portions with cleaved silicon atoms, which are generated at the channel portion or the junction portion between the diffusion layers under the gate oxide film in the CMOS circuit, are terminated by hydrogen atoms. Accordingly, the threshold variation of the transistor is adjusted, the variation in transistor characteristics is suppressed, and the reliability is increased.

In the MRAM process, however, after an MTJ film that constitutes the magnetic tunnel junction of each cell is formed, the upper limit of the subsequent process temperature is defined by the heat resistance of the MTJ film. Hence, after an MTJ film is formed, the upper limit of the process temperature is, e.g., 300° C. to 350° C. At this temperature, sufficiently effective sintering cannot be executed. For this reason, it is difficult to improve the CMOS characteristics in the MRAM.

As a measure, sintering may be executed before formation of an MTJ film. However, Si—H bonds formed in this process are readily cleaved by damage in the subsequent process. As a result, no sufficient sintering effect can be obtained.

### BRIEF SUMMARY OF THE INVENTION

A magnetic random access memory according to a first aspect of the present invention comprises a silicon substrate, a transistor which has a gate electrode formed on the silicon substrate via a gate insulating film and diffusion layers formed in the silicon substrate, a first insulating film formed on the silicon substrate and the transistor, a multilayered interconnection formed in the first insulating film, and a magneto-resistive element formed above the first insulating film, wherein at least some of dangling bonds in the silicon substrate are terminated by silicon-deuterium bonds.

A method of manufacturing a magnetic random access memory according to a second aspect of the present invention comprises forming a gate electrode on a silicon substrate via a gate insulating film and forming diffusion layers in the silicon substrate to form a transistor having the gate electrode and the diffusion layers, forming a first insulating film on the silicon substrate and the transistor, forming a multilayered interconnection in the first insulating film, executing annealing using a gas containing at least deuterium to terminate at least some of dangling bonds in the silicon substrate by silicon-deuterium bonds, and forming a magneto-resistive element above the first insulating film.

### BRIEF DESCRIPTION OF THE SEVERAL VIEWS OF THE DRAWING

FIG. 1 is a sectional view showing a magnetic random access memory according to the first embodiment of the present invention;

FIGS. 2 to 9 are sectional views showing steps in manufacturing the magnetic random access memory according to the first embodiment of the present invention;

FIG. 10 is a sectional view showing a magnetic random access memory according to the second embodiment of the present invention;

FIG. 11 is a sectional view showing steps in manufacturing the magnetic random access memory according to the second embodiment of the present invention;

FIG. 12 is a sectional view showing a magnetic random access memory according to the third embodiment of the present invention;

FIGS. 13 to 15 are sectional views showing steps in manufacturing the magnetic random access memory according to the third embodiment of the present invention;

FIG. 16 is a sectional view showing a magnetic random access memory according to the fourth embodiment of the present invention;

FIGS. 17 and 18 are sectional views showing steps in manufacturing the magnetic random access memory according to the fourth embodiment of the present invention;

FIG. 19 is a sectional view showing a magnetic random access memory according to the fifth embodiment of the present invention;

FIG. 20 is a sectional view showing steps in manufacturing the magnetic random access memory according to the fifth embodiment of the present invention;

FIG. 21 is a sectional view showing a magnetic random access memory according to the sixth embodiment of the present invention;

FIG. 22 is a sectional view showing steps in manufacturing the magnetic random access memory according to the sixth embodiment of the present invention;

FIG. 23 is a block diagram showing the DSL (Digital Subscriber Line) data path portion of a DSL modem so as to explain Application Example 1 of the magnetic random access memories according to the first to fifth embodiments of the present invention;

FIG. 24 is a block diagram showing a cellular telephone terminal so as to explain Application Example 2 of the magnetic random access memories according to the first to fifth embodiments of the present invention;

FIG. 25 is a plan view showing an example in which a magnetic random access memory is applied to a card (MRAM card) as a smart medium which stores media contents so as to explain Application Example 3 of the magnetic random access memories according to the first to fifth embodiments of the present invention;

FIG. 26 is a plan view showing a transfer apparatus to transfer data to an MRAM card;

FIG. 27 is a sectional view showing the transfer apparatus to transfer data to an MRAM card;

FIG. 28 is a sectional view showing a fitting type transfer apparatus to transfer data to an MRAM card; and

FIG. 29 is a sectional view showing a slide type transfer apparatus to transfer data to an MRAM card.

### DETAILED DESCRIPTION OF THE INVENTION

The embodiments of the present invention will be described below with reference to the accompanying drawing. In the following description, the same reference numerals denote the same parts throughout the drawing.

### FIRST EMBODIMENT

In the first embodiment, before an MTJ (Magnetic Tunnel Junction) element is formed, annealing using nitrogen (N₂)+deuterium (D₂) gas is executed. With this process, dangling bonds are terminated by Si-D bonds as well as Si—H bonds.

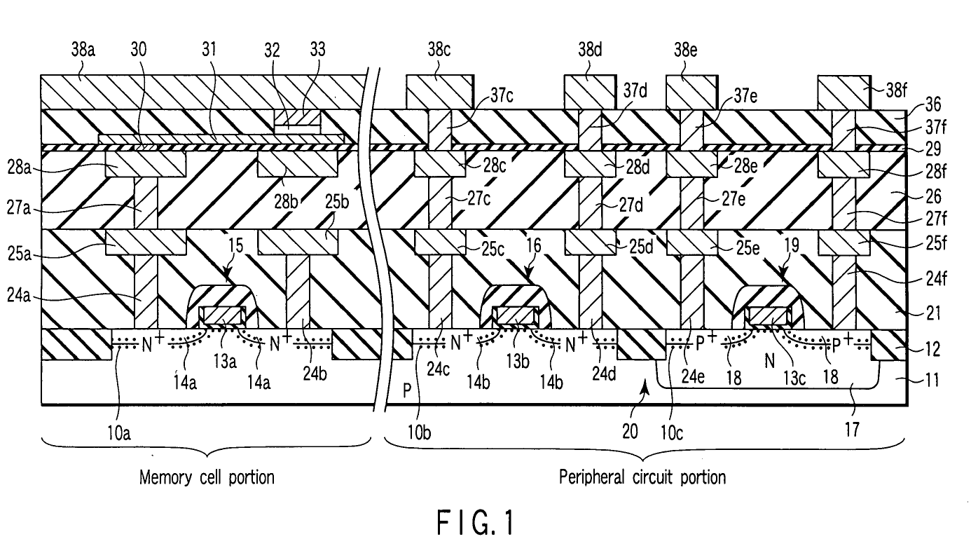

FIG. 1 is a sectional view showing a magnetic random access memory according to the first embodiment of the present invention.

In the memory cell portion, an NMOSFET 15 that functions as a read switching element is formed on a silicon substrate 11. An MTJ element 32 is connected to one of source and drain diffusion layers 14a of the NMOSFET 15 through contacts 24a, 27a, 30, interconnections 25a and 28a, and a lower electrode 31. The MTJ element 32 is connected to an upper interconnection 38a through a contact 33 formed from a hard mask. An interconnection 25b is connected to the other of the source and drain diffusion layers 14a of the NMOSFET 15 through a contact 24b. The upper interconnection 38a functions as a write/read bit line. An interconnection 28b located under the MTJ element 32 functions as a write word line. A gate electrode 13a of the switching element functions as a read word line.

In the peripheral circuit portion, a CMOS circuit 20 having an NMOSFET 16 and a PMOSFET 19 is formed. Contacts 24c, 27c, and 37c and interconnections 25c, 28c, and 38c are connected to one of source and drain diffusion layers 14b of the NMOSFET 16. Contacts 24d, 27d, and 37d and interconnections 25d, 28d, and 38d are connected to the other of the source and drain diffusion layers 14b of the NMOSFET 16. Contacts 24e, 27e, and 37e and interconnections 25e, 28e, and 38e are connected to one of source and drain diffusion layers 18 of the PMOSFET 19. Contacts 24f, 27f, and 37f and interconnections 25f, 28f, and 38f are connected to the other of the source and drain diffusion layers 18 of the PMOSFET 19.

In the memory cell portion and peripheral circuit portion described above, before the MTJ element 32 is formed, annealing using nitrogen (N₂)+deuterium (D₂) gas is executed (details will be described later). With this process, dangling bonds in the silicon substrate 11 are terminated by Si-D bonds as well as Si—H bonds. For this reason, Si-D bond regions 10a, 10b, and 10c are present at least partially in the Si—SiO₂ film interface portions under the gate electrode 13a and gate electrodes 13b and 13c, PN junction portions, and channel portions where dangling bonds are generated. With the above annealing, deuterium atoms also exist in interlayer dielectric films 21, 26, and 29.

The presence of the Si-D bond regions 10a, 10b, and 10c or deuterium atoms in interlayer dielectric films 21, 26, and 29 can be confirmed by using the following methods. For example, atom analysis using a normal SIMS method, monitoring of an infrared absorption characteristic using an FT-IR method, or monitoring of a thermal desorption characteristic using a TDS method can be used.

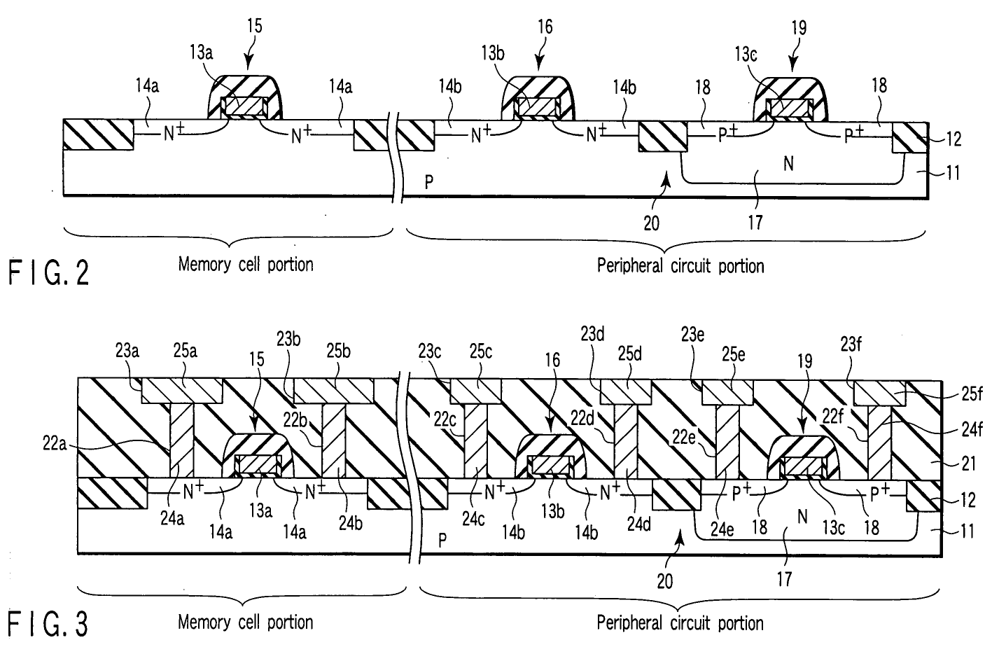

FIGS. 2 to 9 are sectional views showing steps in manufacturing the magnetic random access memory according to the first embodiment of the present invention. The method of manufacturing the magnetic random access memory according to the first embodiment will be described below.

First, as shown in FIG. 2, to electrically disconnect an element region, an element isolation region 12 having an STI (Shallow Trench Isolation) structure and a depth of, e.g., about 2,500 Å is formed in the p-type silicon substrate 11. The gate electrodes 13a, 13b, and 13c are formed on the element region via a gate insulating film (e.g., a silicon oxide film). The n-type diffusion layers 14a and 14b which sandwich the gate electrode 13a and 13b, respectively, are formed in the surface of the silicon substrate 11. An N-well region 17 having a depth of about 2 μm from the upper surface of the silicon substrate 11 is formed. The p-type diffusion layers 18 are formed in the surface of the N-well region 17. In this way, the NMOSFET 15 serving as a read switching element is formed in the memory cell portion. The CMOS circuit 20 having the NMOSFET 16 and PMOSFET 19 is formed in the peripheral circuit portion.

Next, as shown in FIG. 3, the first interlayer dielectric film 21 is formed on the switching element and the CMOS circuit 20. The upper surface of the first interlayer dielectric film 21 is planarized by CMP (Chemical Mechanical Polishing) or resist etch-back. The first interlayer dielectric film 21 is formed from, e.g., a BPSG (Boron Phosphorus Silicate Glass) film and a plasma CVD (Chemical Vapor Deposition) silicon oxide film. The total thickness of these films is about 4,000 Å. At least part of the first interlayer dielectric film 21 may be made of an LPCVD silicon oxide film.

First contact holes 22a, 22b, 22c, 22d, 22e, and 22f are formed in the first interlayer dielectric film 21 by RIE (Reactive Ion Etching) using a photoresist that is patterned by normal lithography. By using a photoresist that is patterned by normal lithography again, first metal interconnection trenches 23a, 23b, 23c, 23d, 23e, and 23f which respectively communicate with the first contact holes 22a, 22b, 22c, 22d, 22e, and 22f are formed.

A 400-Å thick barrier metal film (not shown) made of, e.g., TiN is deposited on the entire surface by CVD. A conductive member having a thickness of about 3,000 Å and made of, e.g., W is formed on the barrier metal film by Blanket-W-CVD. Accordingly, the first contact holes 22a, 22b, 22c, 22d, 22e, and 22f and first metal interconnection trenches 23a, 23b, 23c, 23d, 23e, and 23f are filled with the barrier metal film and conductive member. The barrier metal film and conductive member are removed by CMP until the upper surface of the first interlayer dielectric film 21 is exposed. In this way, the first contacts 24a, 24b, 24c, 24d, 24e, and 24f and the first metal interconnections 25a, 25b, 25c, 25d, 25e, and 25f, which are connected to the n-type diffusion layers 14a and 14b and p-type diffusion layers 18, are formed.

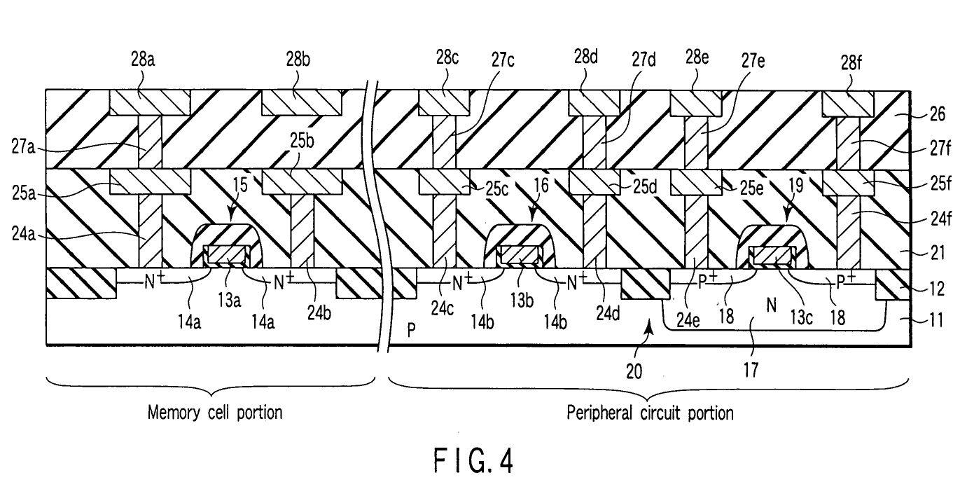

As shown in FIG. 4, the second interlayer dielectric film 26 is deposited on the first interlayer dielectric film 21 and the first metal interconnections 25a, 25b, 25c, 25d, 25e, and 25f. The upper surface of the second interlayer dielectric film 26 is planarized. The second interlayer dielectric film 26 is made of, e.g., a plasma CVD silicon oxide film. The thickness of the film is, e.g., about 5,000 Å. At least part of the second interlayer dielectric film 26 may be made of a BPSG film or an LPCVD silicon oxide film.

After that, the second contacts 27a, 27c, 27d, 27e, and 27f and the second metal interconnections 28a, 28b, 28c, 28d, 28e, and 28f are formed in the second interlayer dielectric film 26 in accordance with the same procedures as those for the first contacts 24a, 24b, 24c, 24d, 24e, and 24f and the first metal interconnections 25a, 25b, 25c, 25d, 25e, and 25f described above.

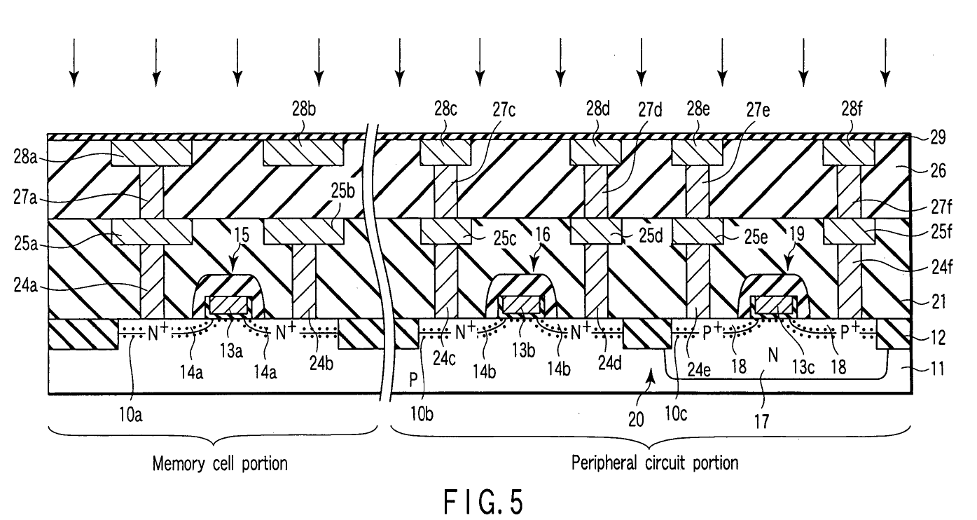

As shown in FIG. 5, the third interlayer dielectric film 29 is deposited on the second interlayer dielectric film 26 and the second metal interconnections 28a, 28b, 28c, 28d, 28e, and 28f. The upper surface of the third interlayer dielectric film 29 is planarized. The third interlayer dielectric film 29 is made of, e.g., a plasma CVD silicon oxide film. The thickness of the film is, e.g., about 500 to 1,500 Å.

In this state, a sintering process using a gas containing deuterium is executed. More specifically, nitrogen (N₂)+deuterium (D₂) gas is supplied into a chamber. The substrate temperature is increased to 400° C. to 450° C. to execute annealing for about 60 min. With this process, silicon dangling bonds in the Si—SiO₂ film interface portions under the gate electrodes 13a, 13b, and 13c, PN junction portions, and channel portions are terminated by Si-D bonds as well as Si—H bonds. The Si-D bond regions 10a, 10b, and 10c exist partially in the silicon substrate 11. The gas used for annealing only needs to contain at least deuterium. The gas also contain, e.g., nitrogen or oxygen in addition to deuterium. If a mixed gas containing deuterium and nitrogen is used for annealing, the mixture ratio is, e.g., D₂:N₂=1:1.

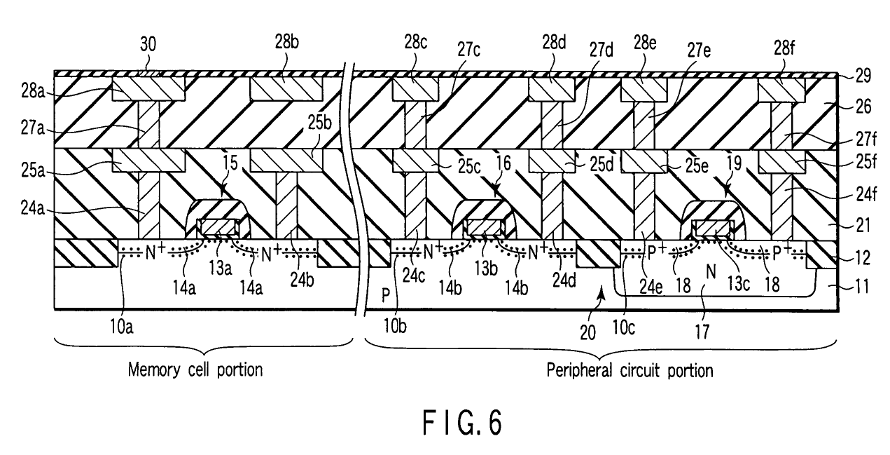

Next, as shown in FIG. 6, the lower electrode contact 30 connected to the second metal interconnection 28a is formed in the third interlayer dielectric film 29.

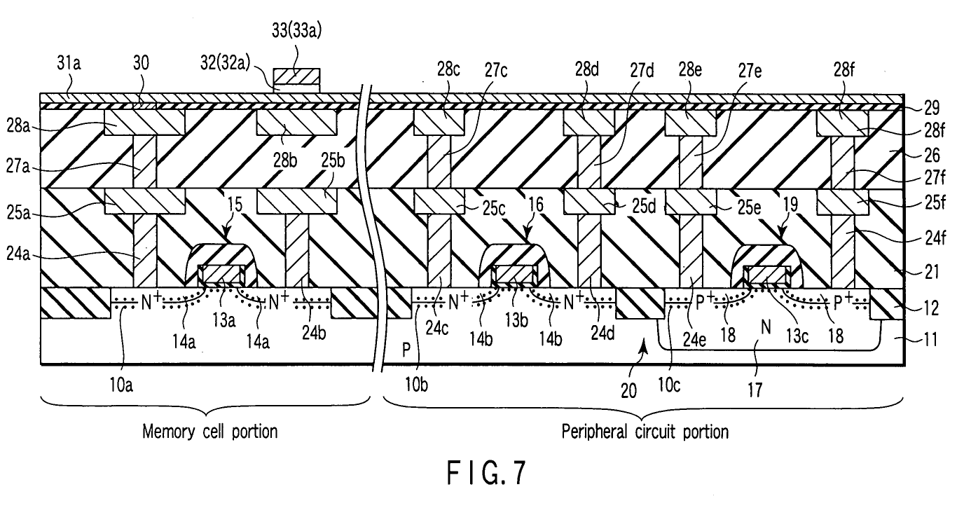

As shown in FIG. 7, a 500-Å thick lower electrode film 31a made of, e.g., Ta, an MTJ film 32a, and a 1,000-Å thick hard mask layer 33a made of, e.g., Ta are sequentially deposited on the third interlayer dielectric film 29 and lower electrode contact 30. An MTJ mask resist (not shown) that is patterned by normal lithography is formed on the hard mask layer 33a. The hard mask layer 33a is patterned by RIE using the mask resist as a mask. Then, the mask resist is peeled by an asher. Subsequently, the MTJ film 32a is separated for respective cells by ion milling or RIE using the hard mask layer 33a as a mask so that the MTJ element 32 is formed. The hard mask layer 33a functions as the contact 33.

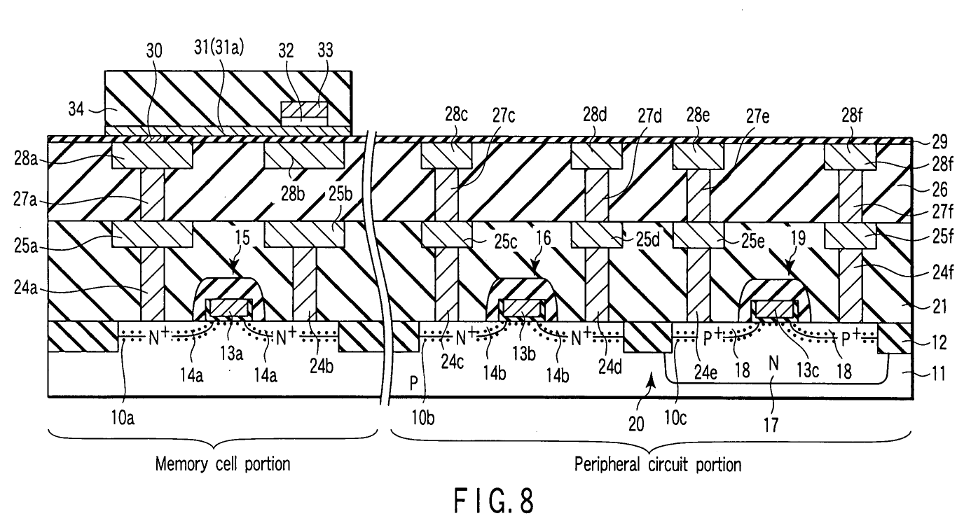

As shown in FIG. 8, to protect the MTJ element 32, a mask resist 34 made of an SiO_{X} film is formed on the entire surface by RF sputtering. The mask resist 34 is patterned by normal lithography. The lower electrode film 31a is separated for the respective cells by RIE using the patterned mask resist 34. Accordingly, the lower electrode 31 is formed.

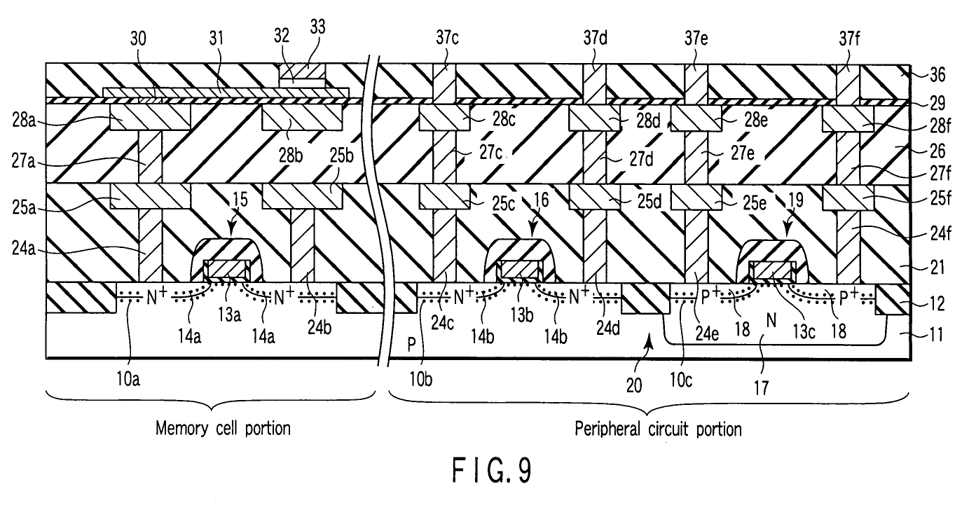

As shown in FIG. 9, a fourth interlayer dielectric film 36 made of an SiO_{X} film is formed on the entire surface by RF sputtering. The upper surface of the fourth interlayer dielectric film 36 is planarized by CMP or resist etch-back. Accordingly, the upper surface of the contact 33 on the MTJ element 32 is exposed. Subsequently, the contacts 37c, 37d, 37e, and 37f for the peripheral circuit are formed and connected to the second metal interconnections 28c, 28d, 28e, and 28f, respectively.

Finally, as shown in FIG. 1, an interconnection member made of, e.g., AlCu is formed on the entire surface by sputtering. After that, a resist mask (not shown) is formed by normal lithography. The interconnection member is patterned by RIE using the resist mask. With this process, the upper interconnection 38a of the MTJ element 32 and the third metal interconnections 38c, 38d, 38e, and 38f of the peripheral circuit portion are formed.

According to the first embodiment, before formation of the MTJ element 32, annealing is executed using nitrogen (N₂)+deuterium (D₂) gas. Hence, silicon dangling bonds generated in the Si—SiO₂ film interface portions under the gate electrodes 13a, 13b, and 13c, PN junction portions, and channel portions can be terminated by Si-D bonds as well as Si—H bonds. The Si-D bond regions 10a, 10b, and 10c are present, where cleavage hardly occurs even in the subsequent process. For this reason, the transistors 15, 16, and 19 which have stable characteristics without any degradation over time and can suitably be used for an MRAM can be formed without executing a hot annealing process after formation of the MTJ element 32.

In the memory cell portion, the threshold variation of the transistor 15 that functions as a switching element can be suppressed, and the reliability can be increased. Hence, the read margin of the MRAM can be increased.

Furthermore, in the memory cell portion, ion milling that easily causes damage is performed to pattern the MTJ element 32. When silicon dangling bonds are terminated only by Si—H bonds, as in the prior art, the Si—H bonds are readily cleaved by ion milling. However, when the silicon dangling bonds are terminated by Si-D bonds as well as Si—H bonds, as in the first embodiment, a structure that is hardly cleaved by ion milling can be formed.

In the peripheral circuit portion, the characteristics of the CMOS circuit 20 comprising the transistors 16 and 19 can be improved.

### SECOND EMBODIMENT

In the second embodiment, the interlayer dielectric film closest to the silicon substrate is formed using deuterated silane (SiD₄) gas. With this arrangement, the ratio of Si-D bonds to Si—H bonds at the terminals of dangling bonds can be made higher than in the first embodiment.

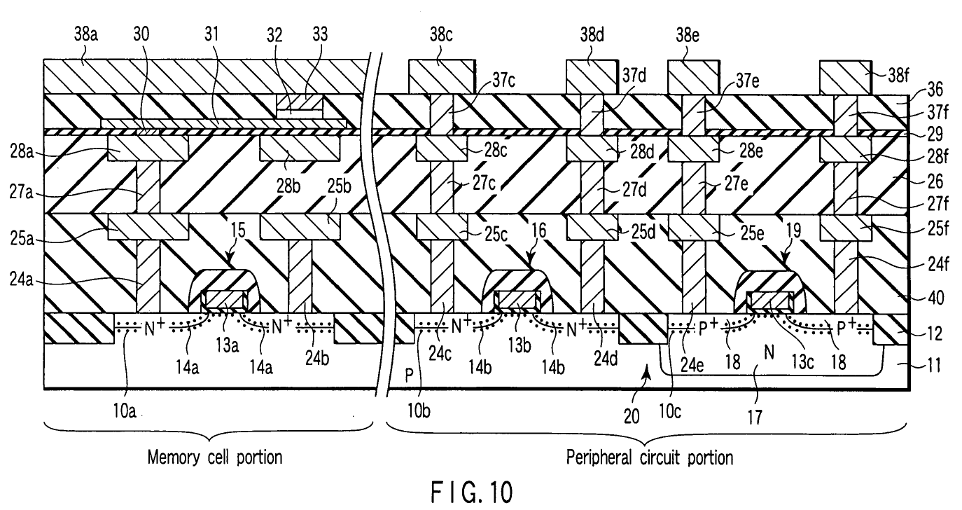

FIG. 10 is a sectional view showing a magnetic random access memory according to the second embodiment of the present invention. As shown in FIG. 10, the second embodiment is different from the first embodiment in that an interlayer dielectric film 40 closest to a silicon substrate 11 is formed using deuterated silane (SiD₄) gas. The interlayer dielectric film 40 at least partially includes one of a BPSG film, LPCVD silicon oxide film, and plasma CVD silicon oxide film.

In the first embodiment, annealing using D₂ (deuterium) gas is performed immediately before formation of the MTJ element 32. Hence, deuterium atoms are present in the entire interlayer dielectric films comprising the first to third interlayer dielectric films 21, 26, and 29.

In the second embodiment, however, the first interlayer dielectric film 40 is formed using deuterated silane (SiD₄) gas. For this reason, deuterium atoms are present not in the entire interlayer dielectric films comprising the first to third interlayer dielectric films 40, 26, and 29 but mainly in the first interlayer dielectric film 40.

Additionally, in the second embodiment, dangling bonds are terminated by Si-D bonds as well as Si—H bonds. For this reason, Si-D bond regions 10a, 10b, and 10c are present partially in the Si—SiO₂ film interface portions under gate electrodes 13a, 13b, and 13c, PN junction portions, and channel portions. The ratio of Si-D bonds to Si—H bonds at the terminals of dangling bonds is higher than in the first embodiment.

FIG. 11 is a sectional view showing steps in manufacturing the magnetic random access memory according to the second embodiment of the present invention. In the manufacturing method of the second embodiment, steps different from the first embodiment will mainly be described.

First, as shown in FIG. 11, an NMOSFET 15 serving as a switching element is formed in the memory cell portion. A CMOS circuit 20 having an NMOSFET 16 and PMOSFET 19 is formed in the peripheral circuit portion.

The first interlayer dielectric film 40 is deposited on the switching element and CMOS circuit 20. The upper surface of the first interlayer dielectric film 40 is planarized by CMP or resist etch-back.

The first interlayer dielectric film 40 is formed from, e.g., a BPSG film and a plasma CVD silicon oxide film. The total thickness of these films is about 4,000 Å.

To deposit the plasma CVD silicon oxide film as the first interlayer dielectric film 40, deuterated silane (SiD₄) is used instead of silane (SiH₄) that is used to form a silicon oxide film by normal plasma CVD. That is, not a combination of SiH₄+O₂ gas or SiH₄+4N₂O gas but a combination of SiD₄+O₂ gas or SiD₄+4N₂O gas is used. In place of deuterated silane (SiD₄), deuterated silane chloride such as deuterated dichlorosilane (SiCl₂D₂) may be used.

Even in depositing a BPSG film as the first interlayer dielectric film 40, deuterated silane (SiD₄) or deuterated silane chloride such as deuterated dichlorosilane (SiCl₂D₂) may be used in place of silane (SiH₄) or dichlorosilane (SiCl₂H₂), which are used as SiH₄+O₂ gas or SiCl₂H₄+O₂ as a material gas of a normal BPSG film.

As the first interlayer dielectric film 40, an LPCVD silicon oxide film may the deposited. Even in forming the LPCVD silicon oxide film, a gas containing deuterated silane (SiD₄) or deuterated silane chloride such as deuterated dichlorosilane (SiCl₂D₂) is used.

As described above, when deuterated silane (SiD₄) or deuterated silane chloride such as deuterated dichlorosilane (SiCl₂D₂) is used to form at least part of the first interlayer dielectric film 40, deuterium (D₄) is incorporated into the silicon substrate 11. Dangling bonds in the Si—SiO₂ film interface portions under the gate electrodes 13a, 13b, and 13c, PN junction portions, and channel portions are terminated by Si-D bonds as well as Si—H bonds. The Si-D bond regions 10a, 10b, and 10c exist.

According to the second embodiment, a BPSG film or plasma CVD silicon oxide film as the first interlayer dielectric film 40 is formed using a gas containing at least deuterium and silane (e.g., a gas containing deuterated silane (SiD₄) or deuterated silane chloride such as deuterated dichlorosilane (SiCl₂D₂)). At this stage of film formation, dangling bonds generated in the Si—SiO₂ film interface portions under the gate electrodes 13a, 13b, and 13c of the MOSFETs 15, 16, and 19, PN junction portions, and channel portions are terminated by Si-D bonds. Hence, the silicon substrate 11 can receive more deuterium (D₄) that in the first embodiment in which annealing using nitrogen (N₂)+deuterium (D₂) gas is executed after formation of the third interlayer dielectric film 29. For this reason, the ratio of Si-D bonds to Si—H bonds at the terminals of dangling bonds can be made higher than in the first embodiment. Accordingly, the resistance against degradation in MOSFET characteristics in the subsequent process can be increased as compared to the first embodiment.

In the second embodiment, an annealing process using nitrogen (N₂)+deuterium (D₂) gas in the first embodiment may be added after formation of the third interlayer dielectric film 29.

### THIRD EMBODIMENT

In the third embodiment, an annealing process using nitrogen (N₂)+deuterium (D₂) gas is additionally executed after a silicon nitride film is formed before formation of an MTJ element in the second embodiment.

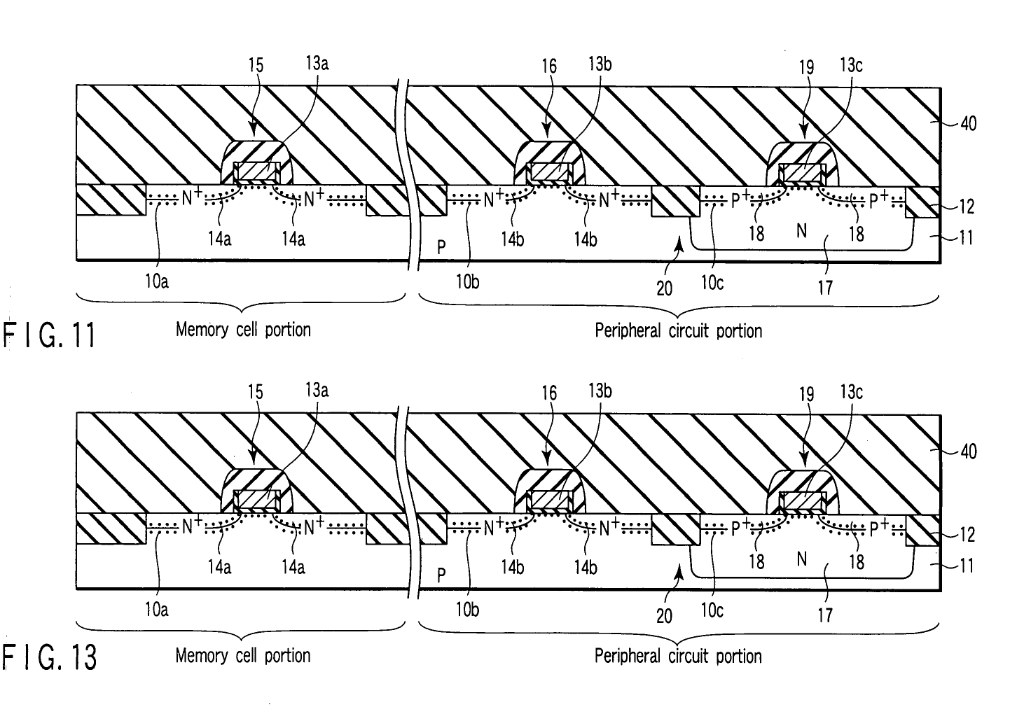

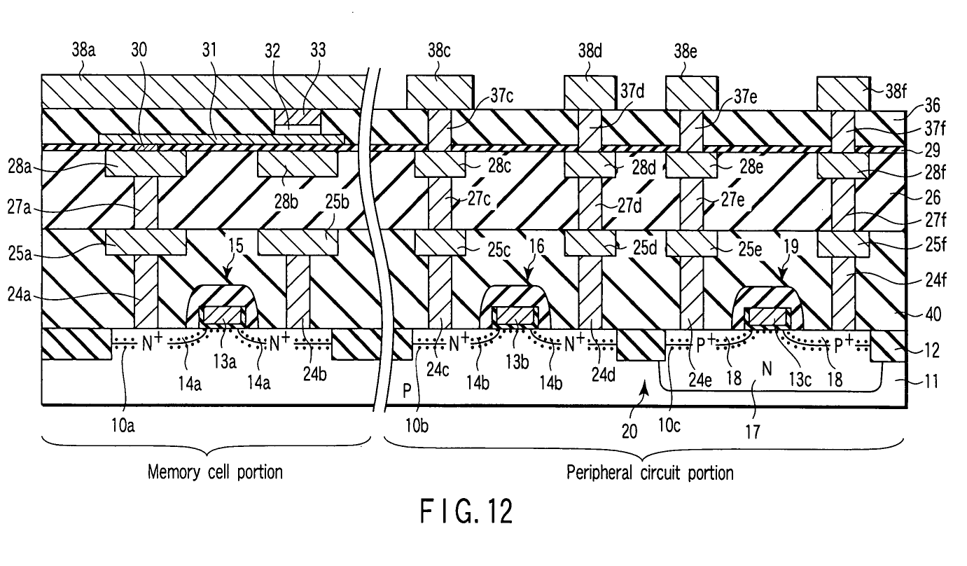

FIG. 12 is a sectional view showing a magnetic random access memory according to the third embodiment of the present invention. As shown in FIG. 12, the third embodiment is different from the second embodiment in that before formation of an MTJ element, a silicon nitride film is formed, and annealing using nitrogen (N₂)+deuterium (D₂) gas is then executed.

In the second embodiment, deuterium atoms mainly exist not in the entire interlayer dielectric films comprising the first to third interlayer dielectric films 40, 26, and 29 but in the first interlayer dielectric film 40.

In the third embodiment, before an MTJ element 32 is formed, a silicon nitride film is formed. Then, annealing using deuterium gas is executed (details will be described later). For this reason, deuterium atoms exist in the entire interlayer dielectric films comprising first to third interlayer dielectric films 40, 26, and 29. Particularly, the first interlayer dielectric film 40 contains many deuterium atoms.

In the third embodiment, dangling bonds are terminated by Si-D bonds as well as Si—H bonds. Hence, Si-D bond regions 10a, 10b, and 10c are present at least partially in the Si—SiO₂ film interface portions under gate electrodes 13a, 13b, and 13c, PN junction portions, and channel portions. The ratio of Si-D bonds to Si—H bonds at the terminals of dangling bonds is higher than in the first and second embodiments.

FIGS. 13 to 15 are sectional views showing steps in manufacturing the magnetic random access memory according to the third embodiment of the present invention. In the manufacturing method of the third embodiment, steps different from the first embodiment will mainly be described.

First, as shown in FIG. 13, an NMOSFET 15 serving as a switching element is formed in the memory cell portion. A CMOS circuit 20 having an NMOSFET 16 and PMOSFET 19 is formed in the peripheral circuit portion.

The first interlayer dielectric film 40 formed from, e.g., a BPSG film, LPCVD silicon oxide film, or plasma CVD silicon oxide film is deposited on the switching element and CMOS circuit 20.

The first interlayer dielectric film 40 is deposited in accordance with the same procedures as in the second embodiment by using deuterated silane (SiD₄) or deuterated silane chloride such as deuterated dichlorosilane (SiCl₂D₂). As a result, deuterium (D₄) is incorporated into a silicon substrate 11. At least some of dangling bonds in the Si—SiO₂ film interface portions under the gate electrodes 13a, 13b, and 13c, PN junction portions, and channel portions are terminated by Si-D bonds. The Si—D bond regions 10a, 10b, and 10c exist.

After that, the upper surface of the first interlayer dielectric film 40 is planarized by CMP or resist etch-back.

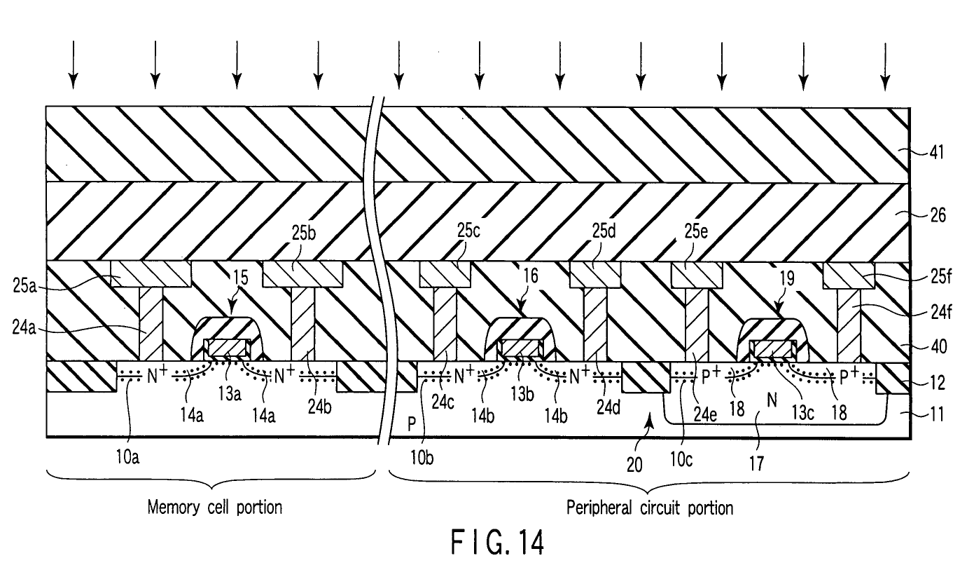

Next, as shown in FIG. 14, the second interlayer dielectric film 26 is formed on the first interlayer dielectric film 40. A silicon nitride film 41 is formed on the second interlayer dielectric film 26. The silicon nitride film 41 is deposited by plasma CVD using, e.g., deuterated silane (SiD₄)+nitrogen (N₂) gas. For this reason, deuterium (D₄) is further incorporated into the silicon substrate 11. In forming the silicon nitride film 41, deuterated silane chloride such as deuterated dichlorosilane (SiCl₂D₂) may be used in place of deuterated silane (SiD₄).

In this state, nitrogen (N₂)+deuterium (D₂) gas is supplied into a chamber. The substrate temperature is increased to 400° C. to 450° C. to execute annealing for about 60 min. With this process, deuterium (D₄) is further incorporated into the silicon substrate 11. Dangling bonds in the Si—SiO₂ film interface portions under the gate electrodes 13a, 13b, and 13c, PN junction portions, and channel portions are further terminated by Si-D bonds.

After the annealing, the silicon nitride film 41 is peeled and removed by, e.g., CDE (Chemical Dry Etching).

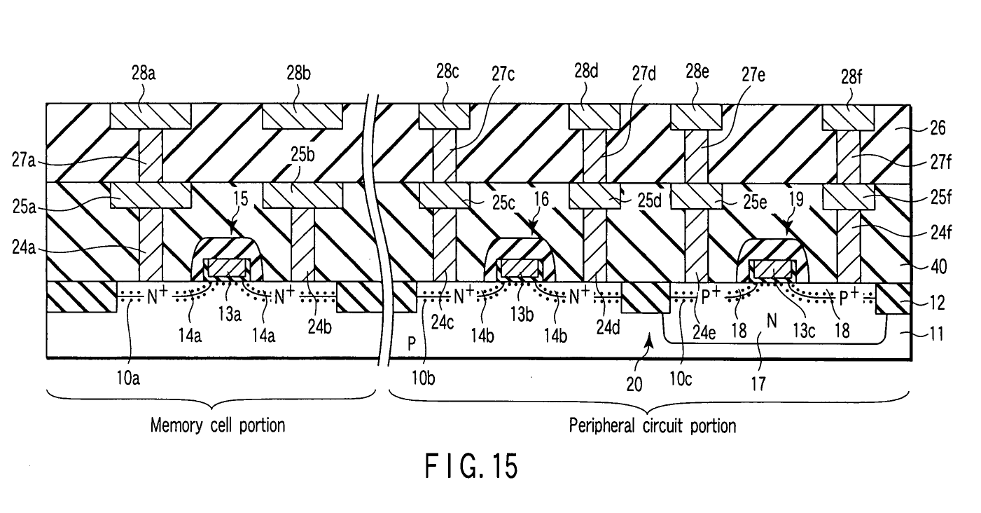

As shown in FIG. 15, second contacts 27a, 27c, 27d, 27e, and 27f and second metal interconnections 28a, 28b, 28c, 28d, 28e, and 28f are formed in the second interlayer dielectric film 26 in accordance with the same procedures as in the first embodiment. Subsequent processes are the same as in the first embodiment, and a description thereof will be omitted.

According to the third embodiment, since a BPSG film or plasma CVD silicon oxide film as the first interlayer dielectric film 40 is formed using a gas containing deuterium (e.g., a gas containing deuterated silane (SiD₄) or deuterated dichlorosilane (SiCl₂D₂)), the same effect as in the second embodiment can be obtained.

In addition, the silicon nitride film 41 is formed using deuterated silane (SiD₄) gas and annealed using nitrogen (N₂)+deuterium (D₂) gas. With this process, deuterium (D₂) can be more effectively incorporated into the silicon substrate 11 than in the first and second embodiments. As a consequence, the ratio of Si-D bonds to Si—H bonds at the terminals of dangling bonds can be made higher than in the first embodiment. Accordingly, the resistance against degradation in MOSFET characteristics in the subsequent process can be increased as compared to the first and second embodiments.

In the third embodiment, the interlayer dielectric film 40 may be formed using not a gas containing deuterium but normal silane (SiH₄) gas.

### FOURTH EMBODIMENT

In the fourth embodiment, the gate electrodes of transistors are formed using deuterated silane (SiD₄) gas. With this arrangement, the radio of Si-D bonds to Si—H bonds at the terminals of dangling bonds can be made higher than in the above embodiments.

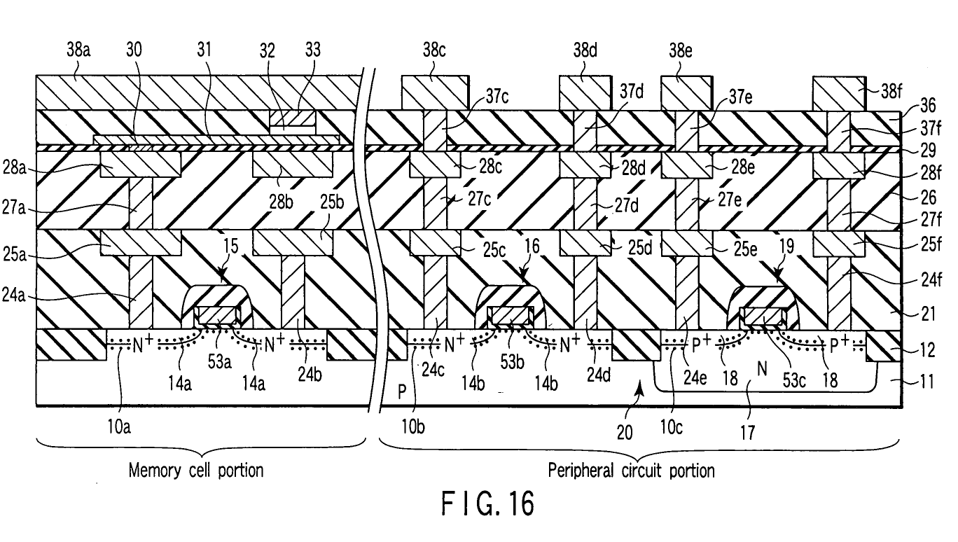

FIG. 16 is a sectional view showing a magnetic random access memory according to the fourth embodiment of the present invention. As shown in FIG. 16, the fourth embodiment is different from the first embodiment in that a polysilicon film 52 for gate electrodes 53a, 53b, and 53c is formed using deuterated silane (SiD₄) gas. Deuterium atoms exist in the gate electrodes 53a, 53b, and 53c.

Additionally, in the fourth embodiment, the number of Si-D bond regions 10a, 10b, and 10c that exist in the Si—SiO₂ film interface portions under the gate electrodes 53a, 53b, and 53c, PN junction portions, and channel portions is larger than in the above embodiments.

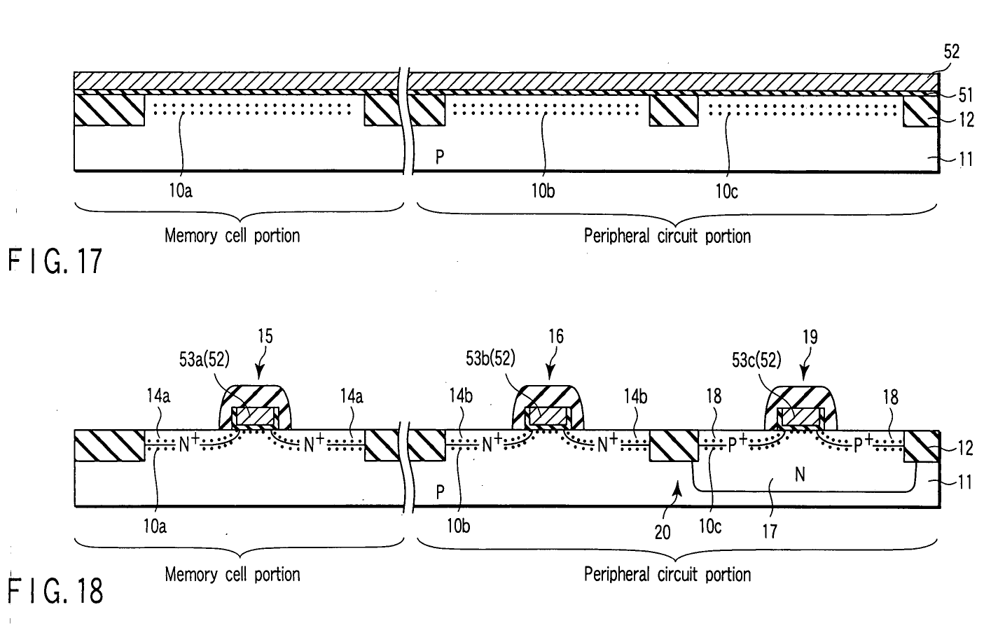

FIGS. 17 and 18 are sectional views showing steps in manufacturing the magnetic random access memory according to the fourth embodiment of the present invention. In the manufacturing method of the fourth embodiment, steps different from the first embodiment will mainly be described.

As shown in FIG. 17, a native oxide film on a silicon substrate 11 is removed. In this state, a thermal oxide film 51 having a thickness of about 60 Å is formed on the silicon substrate 11. Subsequently, the substrate temperature is increased to 600° C. to 700° C. In this state, deuterated silane (SiD₄) gas is supplied in place of normal silane gas (SiH₄). The polysilicon film 52 for the gate electrodes 53a, 53b, and 53c is deposited by LPCVD. In forming the polysilicon film 52, not deuterated silane (SiD₄) but deuterated silane chloride such as deuterated dichlorosilane (SiCl₂D₂) may be used.

As shown in FIG. 18, the polysilicon film 52 is patterned by normal lithography and RIE to form the gate electrodes 53a, 53b, and 53c. Next, ion implantation is performed using the gate electrodes 53a, 53b, and 53c as a mask, thereby forming diffusion layers. Sidewalls are formed. Ion implantation is performed again to form diffusion layers. A silicon nitride film serving as a barrier is formed on each of the gate electrodes 53a, 53b, and 53c. Subsequent processes are the same as in the first embodiment. However, the annealing process using nitrogen (N₂)+deuterium (D₂) gas may be omitted.

To keep the resistance of the polysilicon film 52 low as required for the transistor operation, a process for doping phosphorus (P) into the polysilicon film 52 or a process for depositing WSi (tungsten silicide) on the polysilicon film 52 may be combined.

According to the fourth embodiment, when the gate electrodes 53a, 53b, and 53c made of polysilicon are formed, silicon dangling bonds in the MOSFET regions are exposed to a deuterium atmosphere. For this reason, the silicon dangling bonds can be bonded by deuterium at an earlier stage than in the first to third embodiments. Consequently, a majority of dangling bonds are terminated by Si-D bonds. Accordingly, the resistance against degradation in MOSFET characteristics in the subsequent process can be increased as compared to the first to third embodiments.

In the fourth embodiment, the second embodiment or third embodiment may be combined.

### FIFTH EMBODIMENT

In the fifth embodiment, the gate insulating film of a transistor is formed by using deuterium (D₂) gas, thereby making the ratio of Si-D bonds to Si—H bonds at the terminals of dangling bonds higher than in the above embodiments.

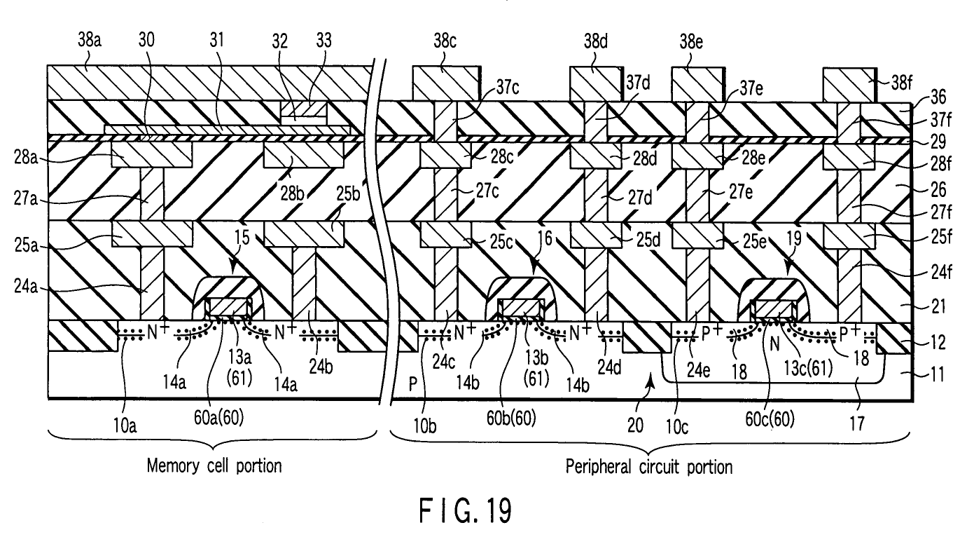

FIG. 19 is a sectional view of a magnetic random access memory according to the fifth embodiment of the present invention. The fifth embodiment is different from the first embodiment in that since a thermal oxide film for gate insulating films 60a, 60b, and 60c are formed by using deuterium (D₂) gas, deuterium atoms are present in the gate insulating films 60a, 60b, and 60c.

Additionally, in the fifth embodiment, the number of Si-D bond regions 10a, 10b, and 10c that exist in the Si—SiO₂ film interface portions, PN junction portions, and channel portions under gate electrodes 13a, 13b, and 13c is larger than in the above embodiments.

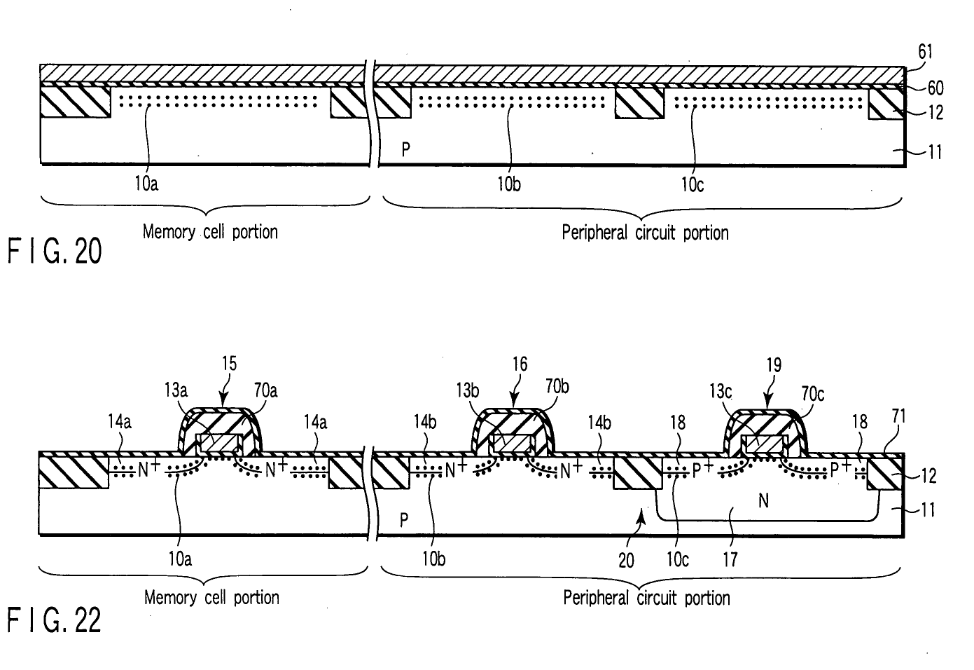

FIG. 20 is a sectional view showing steps in manufacturing the magnetic random access memory according to the fifth embodiment of the present invention. In the manufacturing method of the fifth embodiment, steps different from the first embodiment will mainly be described.

As shown in FIG. 20, a native oxide film on a silicon substrate 11 is removed. In this state, a thermal oxide film 60 having a thickness of about 60 Å is formed on the silicon substrate 11 by thermal oxidation. The thermal oxide film 60 is formed by using deuterium (D₂)+oxygen (O₂) gas. Next, a gate electrode material (e.g., polysilicon) 61 is formed on the thermal oxide film 60. The subsequent process is the same as in the first embodiment. The annealing process using nitrogen (N₂)+deuterium (D₂) gas may be omitted.

According to the fifth embodiment, when the gate insulating films 60a, 60b, and 60c are formed, the silicon dangling bonds in the MOSFET regions are exposed to the deuterium atmosphere. For this reason, the silicon dangling bonds can be bonded by deuterium at an earlier stage than in the first to fourth embodiments. Consequently, a majority of dangling bonds are terminated by Si-D bonds. Accordingly, the resistance against degradation in MOSFET characteristics in the subsequent process can be increased as compared to the first to fourth embodiments.

In the fifth embodiment, the second to fourth embodiments may be combined.

### SIXTH EMBODIMENT

In the sixth embodiment, insulating films which cover the upper and side surfaces of gate electrodes are formed by using a gas containing deuterium (D₂), thereby making the ratio of Si-D bonds to Si—H bonds at the terminals of dangling bonds higher than in the first to third embodiments.

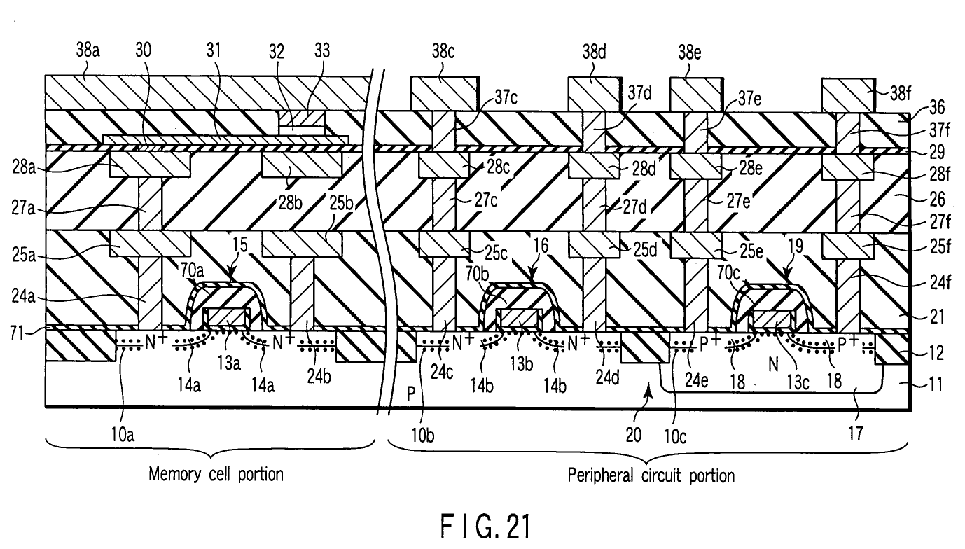

FIG. 21 is a sectional view of a magnetic random access memory according to the sixth embodiment of the present invention. The sixth embodiment is different from the first embodiment in that since insulating films 70a, 70b, 70c, and 71 which cover the upper and side surfaces of gate electrodes 13a, 13b, and 13c are formed by using a gas containing deuterium (D₂), deuterium atoms are present in the insulating films 70a, 70b, 70c, and 71. The insulating films 70a, 70b, 70c, and 71 also cover the upper surface of a silicon substrate 11, including the upper surfaces of n-type diffusion layers 14a and 14b.

Additionally, in the sixth embodiment, the number of Si-D bond regions 10a, 10b, and 10c that exist in the Si—SiO₂ film interface portions, PN junction portions, and channel portions under gate electrodes 13a, 13b, and 13c is larger than in the first to third embodiments.

FIG. 22 is a sectional view showing steps in manufacturing the magnetic random access memory according to the sixth embodiment of the present invention. In the manufacturing method of the sixth embodiment, steps different from the first embodiment will mainly be described.

As shown in FIG. 22, a gate insulating film (e.g., a silicon oxide film) is formed on the silicon substrate 11. Then, the gate electrodes 13a, 13b, and 13c are formed on the gate insulating film. Next, the n-type diffusion layers 14a and 14b, an N-well region 17, and p-type diffusion layers 18 are formed. In this way, an NMOSFET 15 serving as a read switching element is formed in the memory cell portion. A CMOS circuit 20 having an NMOSFET 16 and a PMOSFET 19 is formed in the peripheral circuit portion.

The first insulating films 70a, 70b, and 70c are formed on the upper and side surfaces of the gate electrodes 13a, 13b, and 13c. The second insulting film 71 is formed on the first insulating films 70a, 70b, and 70c and silicon substrate 11. The first and second insulating films 70a, 70b, 70c, and 71 are made of, e.g., silicon nitride films. These films are formed by LPCVD using dichlorosilane (SiCl₂H₂)+deuterated ammonia (ND₃) gas. The subsequent process is the same as in the first embodiment. The annealing process using nitrogen (N₂)+deuterium (D₂) gas may be omitted.

According to the sixth embodiment, when the insulating films 70a, 70b, 70c, and 71 which cover the upper and side surfaces of the gate electrodes are formed, the silicon dangling bonds in the MOSFET regions are exposed to the deuterium atmosphere. For this reason, the silicon dangling bonds can be bonded by deuterium at an earlier stage than in the first to third embodiments. Consequently, a majority of dangling bonds are terminated by Si-D bonds. Accordingly, the resistance against degradation in MOSFET characteristics in the subsequent process can be increased as compared to the first to third embodiments.

In the sixth embodiment, the second to fifth embodiments may be combined.

Various changes and modifications can be made for the first to sixth embodiments of the present invention.

For example, the multilayered interconnection under the MTJ element 32 includes two layers. The number of layers of the multilayered interconnection may be changed by forming third contacts and third metal interconnections. Additional interconnections may be appropriately formed at necessary portions.

The memory cell portion is not limited to the 1 MTJ+1 transistor structure described in the above embodiments. The structure of the memory cell portion may be modified in various ways.

In addition, deuterium may be used in forming a gate oxide film. With this method, dangling bonds in the Si—SiO₂ film interfaces can be more effectively terminated than in the fourth embodiment. In this case, for example, the substrate temperature is set to 850° C. In this state, a mixed gas containing deuterium (D₂)+oxygen (O₂) is supplied to oxidize the surface of the silicon substrate. Then, polysilicon electrodes can be continuously formed.

To terminate dangling bonds in the Si—SiO₂ film interfaces, deuterium may be introduced into the interfaces by using deuterium for the sidewall insulating films (e.g., silicon nitride films) of the gate electrodes.

As the gate electrode material, for example, polysilicon or a multilayered structure of polysilicon and a polymetal (e.g., W—Si) can be used.

As the insulting films which covers the upper and side surfaces of the gate electrodes, for example, silicon nitride films containing deuterium can be used.

The gate electrodes are formed by, e.g., the following process. First, the surface of the silicon substrate is oxidized. Then, a gate electrode material (e.g., a polymetal film) and a cap member (e.g., a silicon nitride film) are deposited. The gate electrode material is patterned by RIE to form the gate electrodes. Next, an oxidation process is executed to oxide the side surfaces of the gate electrodes to form sidewall insulating films. After that, the entire surface is covered with an insulating film (e.g., silicon nitride film containing deuterium).

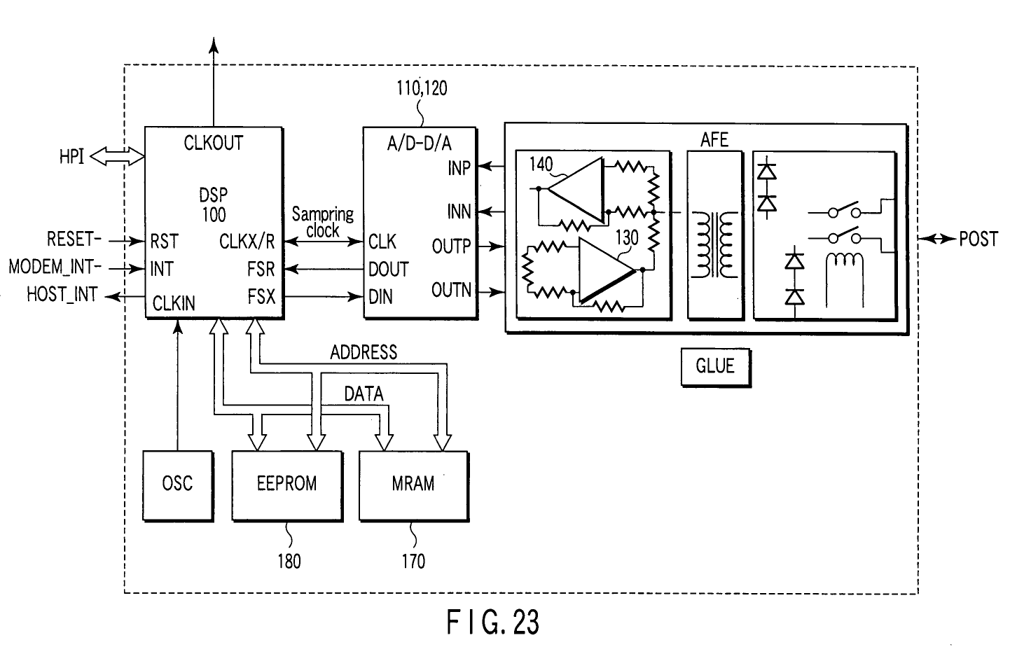

The magnetic random access memories (semiconductor memory devices) according to the first to sixth embodiments of the present invention can be applied to various apparatuses. FIGS. 23 to 29 show application examples.

### APPLICATION EXAMPLE 1

FIG. 23 shows the DSL (Digital Subscriber Line) data path portion of a DSL modem. This modem includes a programmable digital signal processor (DSP) 100, analog/digital (A/D) converter 110, digital/analog (D/A) converter 120, transmission driver 130, and receiver amplifier 140.

FIG. 23 does not illustrate a band pass filter. Instead, a magnetic random access memory (MRAM) 170 according to one of the embodiments and an EEPROM 180 are illustrated as optional memories of various types to hold a line code program (a program which is executed by the DSP to select and operate a modem in accordance with encoded subscriber line information and transmission conditions (line code; QAM, CAP, RSK, FM, AM, PAM, DWMT, and the like)).

In Application Example 1, two kinds of memories, i.e., the magnetic random access memory 170 and EEPROM 180 are used as memories to hold the line code program. The EEPROM 180 may be replaced with a magnetic random access memory. That is, instead of using two types of memories, only magnetic random access memories may be used.

### APPLICATION EXAMPLE 2

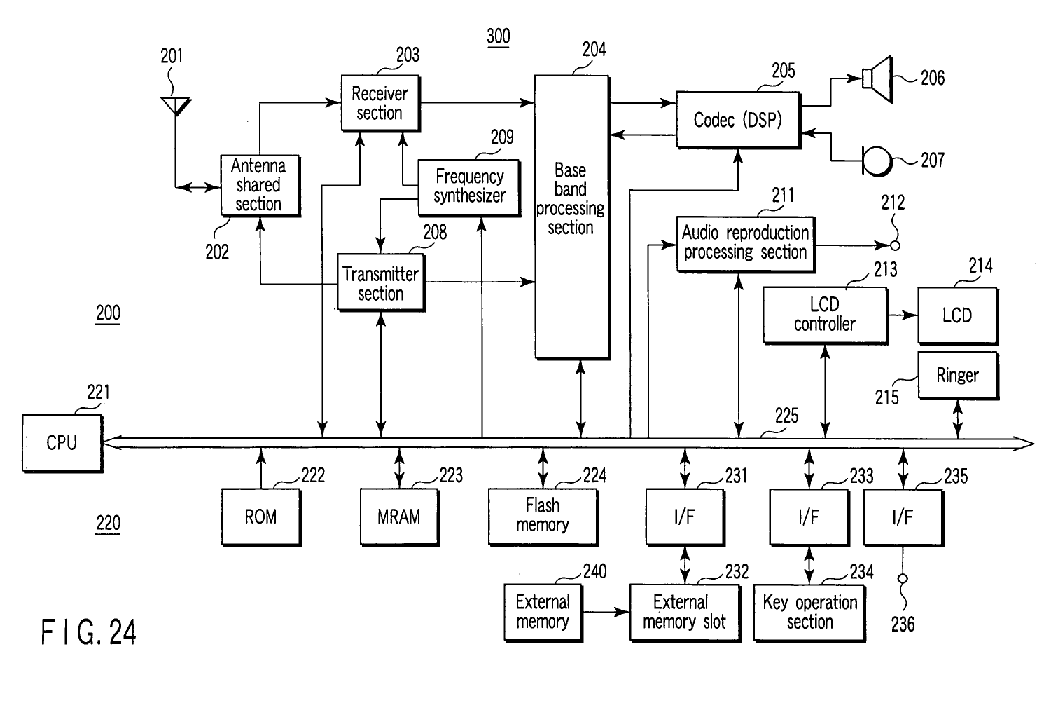

FIG. 24 shows a cellular telephone terminal 300 as another application example. A communication section 200 which implements a communication function comprises a transmitting/receiving antenna 201, an antenna shared section 202, a receiver section 203, a base band processing section 204, a DSP 205 used as a voice codec, a loudspeaker (receiver) 206, a microphone (transmitter) 207, a transmitter section 208, and a frequency synthesizer 209.

The cellular telephone terminal 300 has a control section 220 which controls the sections of the cellular telephone terminal. The control section 220 is a microcomputer which is formed by connecting a CPU 221, a ROM 222, a magnetic random access memory (MRAM) 223 according to one of the embodiments, and a flash memory 224 through a CPU bus 225. The ROM 222 stores, in advance, a program to be executed by the CPU 221 and data necessary for display fonts and the like. The MRAM 223 is mainly used as a work area where the CPU 221 stores, as needed, data midway through calculation during executing the program, or data exchanged between the control section 220 and the respective sections are temporarily stored. Even when the cellular telephone terminal 300 is powered off, the flash memory 224 stores, e.g., the immediately preceding set conditions, so the same set conditions can be used when the cellular telephone terminal is powered on again. Accordingly, even when the cellular telephone terminal is powered off, the stored set parameters are not erased.

The cellular telephone terminal 300 also has an audio reproduction processing section 211, an external output terminal 212, an LCD (Liquid Crystal Display) controller 213, an LCD 214 for display, and a ringer 215 which generates a ringing signal. The audio reproduction processing section 211 reproduces audio information input to the cellular telephone terminal 300 (or audio information stored in an external memory 240 (to be described later)). The audio information that is reproduced can be transmitted to a headphone or a portable loudspeaker through the external output terminal 212 and extracted to the outside. When the audio reproduction processing section 211 is prepared, audio information can be reproduced. The LCD controller 213 receives display information from, e.g., the CPU 221 through the CPU bus 225, converts the display information into LCD control information to control the LCD 214, and drives the LCD 214 to cause it to perform display.

The cellular telephone terminal 300 also has interface circuits (I/Fs) 231, 233, and 235, the external memory 240, an external memory slot 232, a key operation section 234, and an external input/output terminal 236. The external memory slot 232 receives the external memory 240 such as a memory card. The external memory slot 232 is connected to the CPU bus 225 through the interface circuit (I/F) 231. As described above, when the slot 232 is prepared in the cellular telephone terminal 300, information in the cellular telephone terminal 300 can be written in the external memory 240. Alternatively, information (e.g., audio information) stored in the external memory 240 can be input to the cellular telephone terminal 300. The key operation section 234 is connected to the CPU bus 225 through the interface circuit (I/F) 233. Key input information input from the key operation section 234 is transmitted to, e.g., the CPU 221. The external input/output terminal 236 is connected to the CPU bus 225 through the interface circuit (I/F) 233 and functions as a terminal in inputting various kinds of external information to the cellular telephone terminal 300 or outputting information externally from the cellular telephone terminal 300.

In Application Example 2, the ROM 222, MRAM 223, and flash memory 224 are used. The flash memory 224 may be replaced with a magnetic random access memory. The ROM 222 may also be replaced with a magnetic random access memory.

### APPLICATION EXAMPLE 3

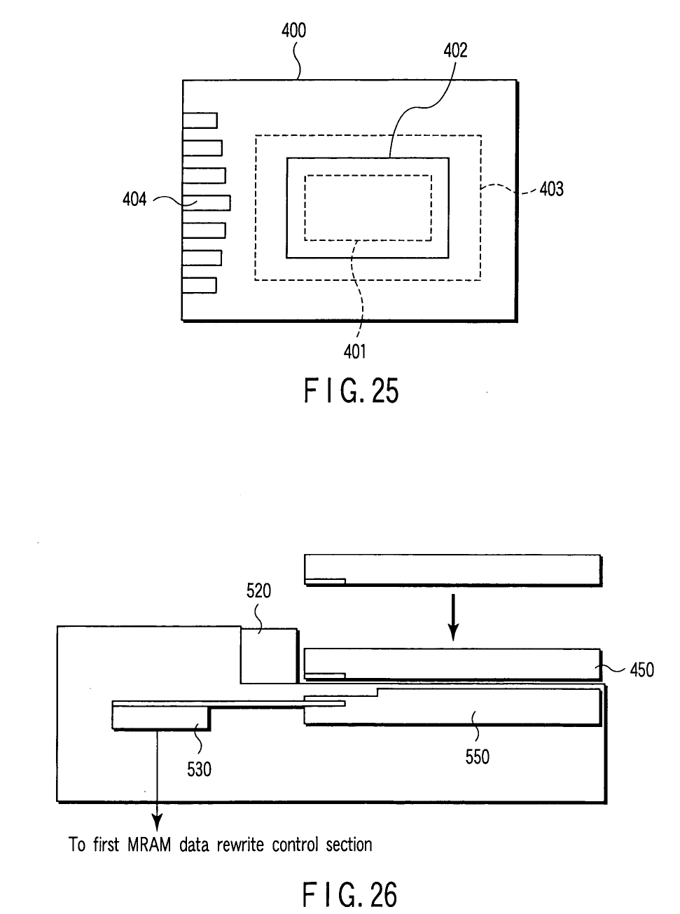

FIGS. 25 to 29 show an example in which a magnetic random access memory is applied to a card (MRAM card) as a smart medium which stores media contents.

As shown in FIG. 25, an MRAM card main body 400 incorporates an MRAM chip 401. An opening portion 402 is formed in the card main body 400 at a position corresponding to the MRAM chip 401 so the MRAM chip 401 is exposed. The opening portion 402 has a shutter 403. When the MRAM card is carried, the MRAM chip 401 is protected by the shutter 403. The shutter 403 is made of a material such as a ceramic capable of shielding an externally magnetic field. When data is to be transferred, the shutter 403 is opened to expose the MRAM chip 401. An external terminal 404 is used to extract content data stored in the MRAM card.

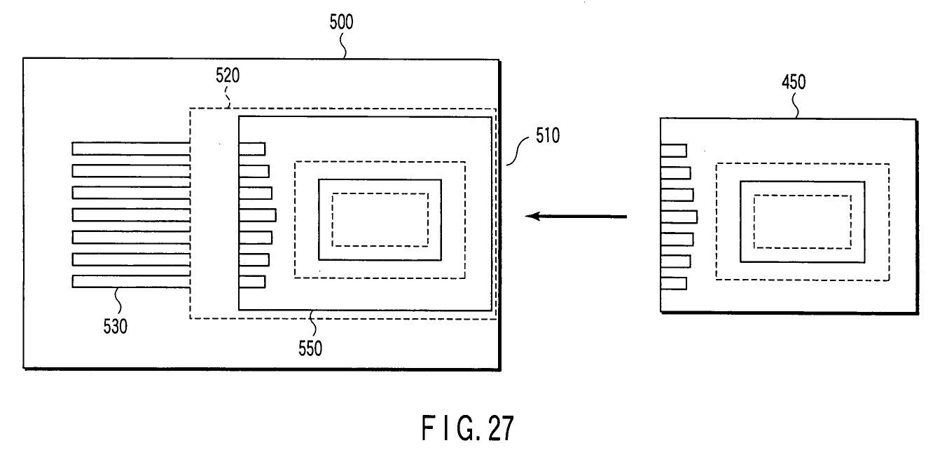

FIGS. 26 and 27 are plan and sectional views showing a card insertion type transfer apparatus which is used to transfer data to the MRAM card. A second MRAM card 450 used by an end user is inserted from an insertion portion 510 of a transfer apparatus 500, as indicated by the arrow, and pushed into until the card abuts against a stopper 520. The stopper 520 also functions as a member to position a first MRAM 550 and the second MRAM card 450. When the second MRAM card 450 is located at a predetermined position, a control signal is supplied from a first MRAM rewrite control section to an external terminal 530. Accordingly, data stored in the first MRAM 550 is transferred to the second MRAM card 450.

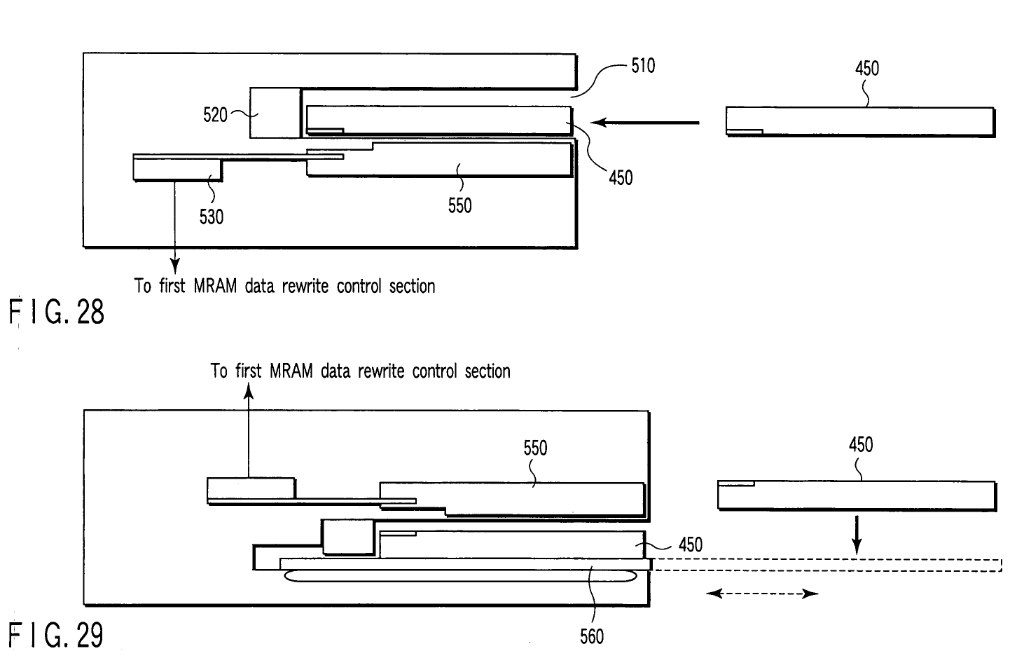

FIG. 28 shows a fitting type transfer apparatus. In this transfer apparatus, the second MRAM card 450 is fitted on the first MRAM 550 with reference to the stopper 520, as indicated by the arrow. The transfer method is the same as in the card insertion type, and a description thereof will be omitted.

FIG. 29 shows a slide type transfer apparatus. The transfer apparatus 500 has a sliding tray 560, like a CD-ROM drive or DVD drive. The sliding tray 560 moves, as indicated by the arrow. When the sliding tray 560 moves to the position indicated by the broken line, the second MRAM card 450 is mounted on the sliding tray 560 and conveyed into the transfer apparatus 500. The structure that conveys the second MRAM card 450 until it abuts against the stopper 520 and the transfer method are the same as in the card insertion type, and a description thereof will be omitted.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

1. A magnetic random access memory comprising:
a silicon substrate;
a transistor which has a gate electrode formed on the silicon substrate via a gate insulating film and diffusion layers formed in the silicon substrate;
a first insulating film formed on the silicon substrate and the transistor;
a multilayered interconnection formed in the first insulating film; and
a magneto-resistive element formed above the first insulating film,
wherein at least some of dangling bonds in the silicon substrate are terminated by silicon-deuterium bonds.

2. The memory according to claim 1, wherein the silicon-deuterium bonds exist at least partially in an interface portion between the gate insulating film and the silicon substrate under the gate electrode, junction portions of the diffusion layers, and a channel portion.

3. The memory according to claim 1, wherein deuterium atoms exist in the first insulating film.

4. The memory according to claim 1, wherein deuterium atoms exist in the gate electrode.

5. The memory according to claim 1, wherein deuterium atoms exist in the gate insulating film.

6. The memory according to claim 1, further comprising a second insulting film which is formed on the silicon substrate, including upper surfaces of the diffusion layers, and upper and side surfaces of the gate electrode and contains deuterium atoms.

7. The memory according to claim 1, wherein the magneto-resistive element is electrically connected to the transistor through part of the multilayered interconnection, and the transistor is a data read switching element.

8. The memory according to claim 1, wherein the transistor is a transistor of a CMOS circuit.

9. A method of manufacturing a magnetic random access memory comprising:
forming a gate electrode on a silicon substrate via a gate insulating film and forming diffusion layers in the silicon substrate to form a transistor having the gate electrode and the diffusion layers;
forming a first insulating film on the silicon substrate and the transistor;
forming a multilayered interconnection in the first insulating film;
executing annealing using a gas containing at least deuterium to terminate at least some of dangling bonds in the silicon substrate by silicon-deuterium bonds; and
forming a magneto-resistive element above the first insulating film.

10. The method according to claim 9, wherein the silicon-deuterium bonds exist at least partially in an interface portion between the gate insulating film and the silicon substrate under the gate electrode, junction portions of the diffusion layers, and a channel portion.

11. The method according to claim 9, wherein the annealing is executed using a gas containing deuterium and nitrogen.

12. The method according to claim 9, wherein deuterium atoms exist in the first insulating film.

13. The method according to claim 9, wherein the magneto-resistive element is electrically connected to the transistor through part of the multilayered interconnection, and the transistor is a data read switching element.

14. The method according to claim 9, wherein the transistor is a transistor of a CMOS circuit.

15. A method of manufacturing a magnetic random access memory comprising:
forming a gate electrode on a silicon substrate via a gate insulating film and forming diffusion layers in the silicon substrate to form a transistor having the gate electrode and the diffusion layers;
forming a first insulating film on the silicon substrate and the transistor by using a gas containing at least deuterium and silane to terminate at least some of dangling bonds in the silicon substrate by silicon-deuterium bonds;
forming a multilayered interconnection in the first insulating film; and
forming a magneto-resistive element above the first insulating film.

16. The method according to claim 15, wherein the gas is one of deuterated silane gas and deuterated silane chloride gas.

17. A method of manufacturing a magnetic random access memory comprising:
forming a gate electrode on a silicon substrate via a gate insulating film and forming diffusion layers in the silicon substrate to form a transistor having the gate electrode and the diffusion layers;
forming a first insulating film on the silicon substrate and the transistor;
forming a silicon nitride film on the first insulating film;
executing annealing using a gas containing at least deuterium to terminate at least some of dangling bonds in the silicon substrate by silicon-deuterium bonds;
removing the silicon nitride film;
forming a multilayered interconnection in the first insulating film; and
forming a magneto-resistive element above the first insulating film.

18. A method of manufacturing a magnetic random access memory comprising:
forming a gate insulating film on a silicon substrate;
forming a gate electrode on the gate insulating film by using a gas containing at least deuterium and silane to terminate at least some of dangling bonds in the silicon substrate by silicon-deuterium bonds;
forming diffusion layers in the silicon substrate to form a transistor having the gate electrode and the diffusion layers;
forming a first insulating film on the silicon substrate and the transistor;
forming a multilayered interconnection in the first insulating film; and
forming a magneto-resistive element above the first insulating film.

19. A method of manufacturing a magnetic random access memory comprising:
forming a gate insulating film on a silicon substrate by using a gas containing at least deuterium to terminate at least some of dangling bonds in the silicon substrate by silicon-deuterium bonds;
forming a gate electrode on the gate insulating film;
forming diffusion layers in the silicon substrate to form a transistor having the gate electrode and the diffusion layers;
forming a first insulating film on the silicon substrate and the transistor;
forming a multilayered interconnection in the first insulating film; and
forming a magneto-resistive element above the first insulating film.

20. A method of manufacturing a magnetic random access memory comprising:
forming a gate insulating film on a silicon substrate and forming a gate electrode on the gate insulating film;
forming diffusion layers in the silicon substrate to form a transistor having the gate electrode and the diffusion layers;
forming a first insulating film on the silicon substrate, including upper surfaces of the diffusion layers, and upper and side surfaces of the gate electrode by using a gas containing at least deuterium to terminate at least some of dangling bonds in the silicon substrate by silicon-deuterium bonds;
forming a second insulting film on the silicon substrate and the transistor;
forming a multilayered interconnection in the second insulating film; and
forming a magneto-resistive element above the second insulating film.
